(19) United States
(12) Patent Application Publication
(10) Pub. No.: US 2026/0157150 A1
(43) Pub. Date: Jun. 4, 2026

(54) ROTATING SHAFT SEALING DEVICE AND PROCESSING APPARATUS FOR SEMICONDUCTOR SUBSTRATE USING THE SAME

(71) Applicant: SEALINK CORP., Seoul (KR)

(72) Inventor: Hee Jang RHEE, Gunpo-si Gyeonggi-do (KR)

(73) Assignee: SEALINK CORP., Seoul (KR)

(21) Appl. No.: 19/091,389

(22) Filed: Mar. 26, 2025

(30) Foreign Application Priority Data
Nov. 29, 2024 (KR) 10-2024-0174281
Dec. 26, 2024 (KR) 10-2024-0197429

(51) Int. Cl. H01L 21/687; C23C 16/458

(52) U.S. Cl. CPC H10P 72/7626; C23C 16/4584; H10P 72/7618

(57) ABSTRACT

A rotating shaft sealing device is provided. The rotating shaft sealing device includes a shaft having one end connected to a semiconductor loading unit to transmit rotational force to the semiconductor loading unit, an outer housing to which the other end of the shaft is fixedly coupled and accommodating the shaft therein, an inner housing surrounding an outer circumferential surface of the shaft and installed on an inner surface of the outer housing, and having one end with a flange connected to a chamber of a semiconductor substrate processing apparatus, one or more bearings provided between the outer housing and the inner housing to enable relative rotation between the outer housing and the inner housing, and a sealing portion including a plurality of seals disposed in the inner housing and the outer housing to seal a gap between the inner housing and the outer housing.

### CROSS-REFERENCE TO RELATED APPLICATIONS

This application claims priority to Korean Patent Application No. 10-2024-0174281 filed on Nov. 29, 2024, and Korean Patent Application No. 10-2024-0197429 filed on Dec. 26, 2024, the entire contents of which are herein incorporated by reference.

### BACKGROUND

### 1. Field

The disclosure relates to a rotating shaft sealing device and a semiconductor substrate processing apparatus using the same, and more particularly to, a rotating shaft sealing device that prevents fluid from leaking between a rotating shaft and a housing, and a semiconductor substrate processing apparatus using the same.

### 2. Description of the Related Art

Processing equipment is used for mass production of integrated circuits. Physical vapor deposition (PVD) such as sputtering and chemical vapor deposition (CVD) using chemical reactions are used to deposit a thin film of a certain thickness on a substrate such as a semiconductor wafer or glass. Examples of PVD include atmospheric pressure CVD (APCVD), low pressure CVD (LPCVD), plasma organic CVD (PECVD), etc. In addition, furnace equipment for heat treatment of substrates is used for film treatment, oxidation, annealing, and diffusion treatment of impurities of semiconductor wafers.

A rotating shaft sealing device for vacuum pressure equipment is used in such semiconductor equipment. The rotating shaft sealing device is provided on an outer circumferential surface of a shaft facing a high pressure region and a low pressure region and rotating between the high pressure region and the low pressure region to seal the high pressure region and the low pressure region with each other.

The rotating shaft sealing device for vacuum pressure equipment of the related art includes a housing and a rotating shaft coupled through the housing. The rotating shaft faces a high pressure region and a low pressure region, and the housing is positioned at a boundary surface between the high pressure region and the low pressure region. In addition, a seal for sealing is provided between the housing and the rotating shaft. The seal for sealing is a magnetic fluid seal, and the magnetic fluid seal is responsible for airtightness during rotational motion like a liquid O-ring by placing magnetic fluid along a magnetic flux line formed by a magnet in a gap between the shaft and a pole piece, but requires cooling at 80° C. or higher, and has a problem that when used for a long time, particles of the magnetic fluid are discharged to the surroundings and contaminate a deposition device. In addition, because the magnetic fluid seal is a seal for rotational motion, sealing in a straight direction is not performed, and has problems that no liquid is sealed and its seal life is shortened under conditions such as liquid entering the seal or liquid aggregating (condensing) near the magnetic fluid.

### SUMMARY

The disclosure is directed to providing a rotating shaft sealing device that does not require a separate supply of lubricant while not using a magnetic fluid seal, thereby making the structure very compact and simple, and a semiconductor substrate processing apparatus using the same.

The disclosure is also directed to providing a rotating shaft sealing device capable of preventing foreign substances such as particles from a semiconductor substrate processing apparatus from flowing into the rotating shaft sealing device, and preventing foreign substances from the rotating shaft sealing device from flowing to the semiconductor substrate processing apparatus, and the semiconductor substrate processing apparatus using the same.

The solutions of the disclosure are not limited to the above-mentioned contents, and other technical problems not mentioned will be clearly understood by one of ordinary skill in the art from the following description.

According to an embodiment of the disclosure, a rotating shaft sealing device mounted on a semiconductor substrate processing apparatus processing a semiconductor substrate while rotating a semiconductor loading unit accommodating the semiconductor substrate includes a shaft having one end connected to the semiconductor loading unit to transmit rotational force to the semiconductor loading unit, an outer housing to which the other end of the shaft is fixedly coupled and accommodating the shaft therein, an inner housing surrounding an outer circumferential surface of the shaft and installed on an inner surface of the outer housing, and having one end with a flange connected to a chamber of the semiconductor substrate processing apparatus, one or more bearings provided between the outer housing and the inner housing to enable relative rotation between the outer housing and the inner housing, and a sealing portion including a plurality of seals disposed in the inner housing and the outer housing to seal a gap between the inner housing and the outer housing.

The one or more bearings may be disposed above the sealing portion so as to be closer to the flange portion of the inner housing coupled to the semiconductor substrate processing apparatus.

The plurality of seals may be lip seals having curved lips formed on an inner circumferential surface of an annular sealing.

Each of the lip seals may have a plurality of curved lip portions provided on one body portion.

At least two of the plurality of curved lip portions may be curved in different directions.

The inner housing may include a cooling water jacket provided in a part surrounding the shaft to cool between the shaft and the inner housing.

The inner housing may include a purge gas inflow port provided in the inner housing to prevent foreign substances from the semiconductor substrate processing apparatus from flowing to the outside of the inner housing.

The gap between the shaft and the inner housing may be in fluid communication with the purge gas inflow port, and purge gas supplied through the purge gas inflow port may flow through the gap.

According to an embodiment of the disclosure, a semiconductor substrate processing apparatus processing a semiconductor substrate includes a semiconductor loading unit rotatably disposed in a chamber, and a rotating shaft sealing device performing a sealing function while rotating the semiconductor loading unit, wherein the rotating shaft sealing device includes a shaft having one end connected to the semiconductor loading unit to transmit rotational force to the semiconductor loading unit, an outer housing to which the other end of the shaft is fixedly coupled and accommodating the shaft therein, an inner housing surrounding an outer circumferential surface of the shaft and installed on an inner surface of the outer housing, and having one end with a flange connected to the chamber of the semiconductor substrate processing apparatus, one or more bearings provided between the outer housing and the inner housing to enable relative rotation between the outer housing and the inner housing, and a sealing portion including a plurality of seals disposed in the inner housing and the outer housing to seal a gap between the inner housing and the outer housing.

### BRIEF DESCRIPTION OF THE DRAWINGS

The above and other features and advantages of the present invention will become more apparent by describing in detail exemplary embodiments thereof with reference to the attached drawings in which:

FIG. 1 is a diagram illustrating a rotating shaft sealing device and a semiconductor substrate processing apparatus according to an embodiment of the disclosure;

FIG. 2 is a perspective view of the rotating shaft sealing device according to an embodiment of the disclosure;

FIG. 3 is a front view of the rotating shaft sealing device of FIG. 2;

FIG. 4 is a plan view of the rotating shaft sealing device of FIG. 2;

FIG. 5 is a cross-sectional view of the rotating shaft sealing device taken along line A-A in FIG. 4; and

FIGS. 6A, 6B, and 6C illustrate various lip seals that may be used in the rotating shaft sealing device according to an embodiment of the disclosure.

### DETAILED DESCRIPTION

Embodiments will be described more fully hereinafter with reference to the accompanying drawings so that they may be easily implemented by one of ordinary skill in the art to which the disclosure belongs. However, the disclosure may be implemented in different forms and should not be construed as being limited to the embodiments set forth herein. In addition, in order to clearly explain an embodiment of the disclosure in the drawings, parts that are not related to the explanation are omitted.

The terms used herein are only used to describe particular embodiments, and are not intended to limit the disclosure. Singular expressions used herein are intended to include plural expressions as well unless the context clearly indicates otherwise.

The terms such as “comprise,” “include,” or “have” used herein may be understood as being intended to specify the presence of stated features, numbers, steps, operations, elements, components, or combinations thereof, but do not preclude the presence or addition of one or more other features, numbers, steps, operations, elements, components, or combinations thereof.

In addition, the following embodiments are provided to more clearly explain to one of average knowledge in the art, and the shape and size of elements in the drawing may be exaggerated for clearer explanation.

Hereinafter, preferred embodiments according to the disclosure will be described with reference to the accompanying drawings.

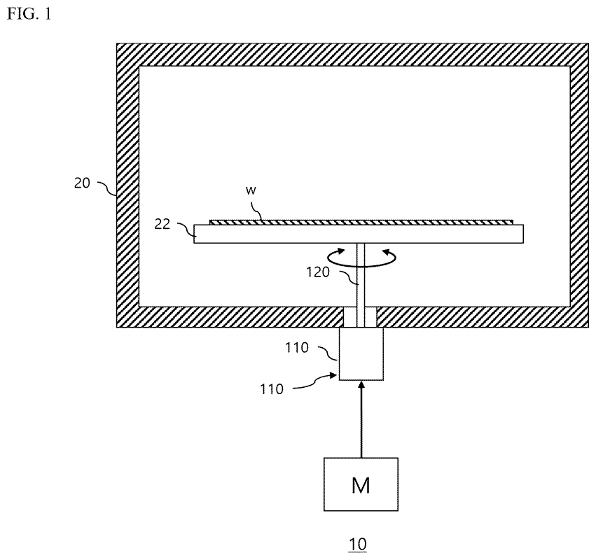

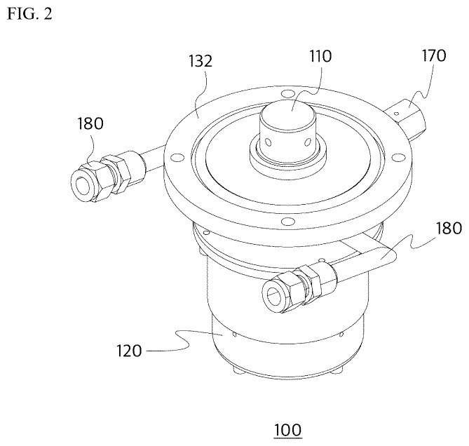

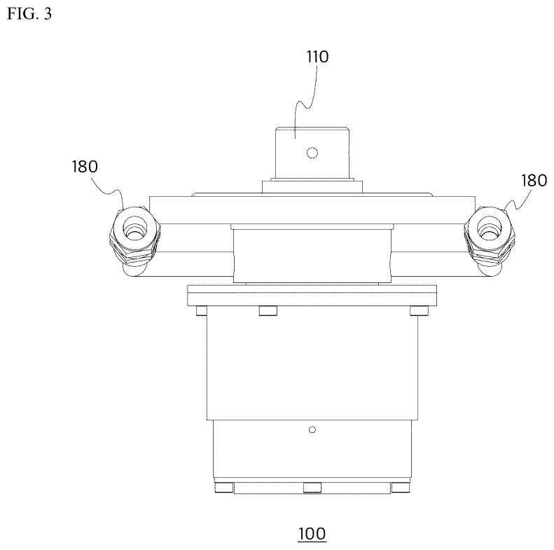

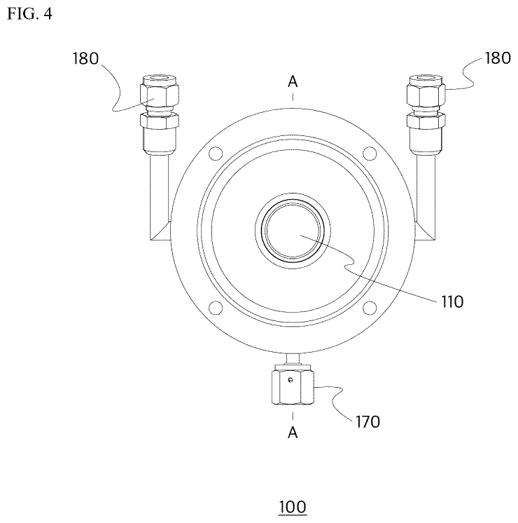

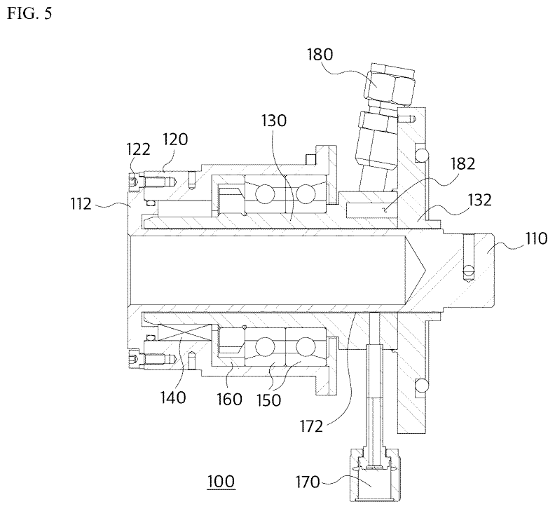

FIG. 1 is a diagram illustrating a rotating shaft sealing device and a semiconductor substrate processing apparatus according to an embodiment of the disclosure. FIG. 2 is a perspective view of the rotating shaft sealing device according to an embodiment of the disclosure. FIG. 3 is a front view of the rotating shaft sealing device of FIG. 2. FIG. 4 is a plan view of the rotating shaft sealing device of FIG. 2. FIG. 5 is a cross-sectional view of the rotating shaft sealing device taken along line A-A in FIG. 4.

Referring to FIG. 1, a semiconductor substrate processing apparatus 10 according to an embodiment of the disclosure may include a rotating shaft sealing device 100 and a chamber 20. Chemical vapor deposition (CVD) equipment, furnace equipment, etching equipment, etc. may be examples of the semiconductor substrate processing apparatus 10. The semiconductor substrate processing apparatus 10 may include a loading unit 22 (susceptor) capable of loading semiconductor wafers inside the chamber 20 and the rotating shaft sealing device 100 rotating the loading unit 22. The rotating shaft sealing device 100 may rotate the loading unit 22 at an appropriate speed and simultaneously prevent process gas in the chamber 20 from flowing to the outside of the chamber 20 or foreign substances outside the chamber 20 from flowing into the chamber 20.

Referring to FIGS. 2 to 5, the rotating shaft sealing device 100 according to an embodiment of the disclosure is provided to rotate the semiconductor loading unit 22. The rotating shaft sealing device 100 may include a shaft 110, an outer housing 120, an inner housing 130, a bearing 150, and a sealing portion 140.

One end of the shaft 110 may be connected to the semiconductor loading unit 22 to rotate the semiconductor loading unit 22. That is, the shaft 110 may transmit rotational force to the semiconductor loading unit 22.

The outer housing 120 may have a hollow shape and be fixedly coupled to the other end of the shaft 110. The outer housing 120 may accommodate the shaft 110 therein. Specifically, the other end of the shaft 110 may include a connection portion 112 having an expanding outer diameter, and the connection portion 112 of the shaft 110 and one end of the outer housing 120 may be coupled to each other through a fastener 122 such as a bolt. Accordingly, the shaft 110 and the outer housing 120 may rotate together.

The inner housing 130 may surround an outer circumferential surface of the shaft 110 and be installed on an inner surface of the outer housing 120. Specifically, the inner housing 130 is inserted between the shaft 110 and the outer housing 120 but is not connected to the shaft 110 and the outer housing 120. Therefore, even when the shaft 110 and the outer housing 120 rotate together, the inner housing 130 may not rotate. A flange 132 connected to the chamber 20 of the semiconductor substrate processing apparatus 10 may be provided on one end of the inner housing 130. Thanks to such a structure, when the outer circumferential surface of the outer housing 120 rotates by receiving rotational force by a pulley, etc., the shaft 110 also rotates together, but the chamber 20 connected to the inner housing 130 and the outer housing 120 may not rotate.

One or more bearings 150 may be provided between the outer housing 120 and the inner housing 130 to enable relative rotation between the outer housing 120 and the inner housing 130.

The sealing portion 140 may include a plurality of seals disposed between the inner housing 130 and the outer housing 120 to seal s gap between the inner housing 130 and the outer housing 120. In the present embodiment, the plurality of seals 140 may be lip seals having curved lips formed on an inner circumferential surface of an annular sealing. In addition, each of the lip seals 140 may have one or more curved lip portions provided on one body portion.

In the present embodiment, two bearings 150 may be provided between the outer housing 120 and the inner housing 130, and may be disposed closer to the flange portion 132 of the inner housing 130 than the sealing portion 140. As shown in FIG. 5, the length of the inner housing 130 is longer than the length of the outer housing 120. Therefore, thanks to a structure in which the plurality of bearings 150 are disposed at an upper end of the outer housing 120, and the sealing portion 140 is disposed at a lower end of the outer housing 120, the outer housing 120 and the shaft 110 may rotate more stably while supporting the inner housing 130 therebetween. Meanwhile, a spacer 160 may be provided to fill a distance between the sealing portion 140 and the bearing 150. In an embodiment, the bearing 150 may be provided approximately at the center of the rotating shaft sealing device 100 to suppress the vibration of the shaft 110 and stably support the shaft 110. In the present embodiment, the bearing 150, which is a thrust bearing, may be a double row angular contact bearing. The double row angular contact bearing 150 may support load applied to the shaft 110 to support the load of the semiconductor loading unit 22. Meanwhile, the spacer 160 may be provided to fill a distance between the bearing 150 and the sealing portion 140.

Meanwhile, the rotating shaft sealing device 100 according to an embodiment of the disclosure may include a cooling water jacket 182. The cooling water jacket 182 may serve to cool heat generated by the friction between the shaft 110 and the inner housing 130 and also cool and protect the sealing portion 140. The cooling water jacket 182 may be provided in the inner housing 130 and provided in a shape surrounding the shaft 110. In addition, a pair of cooling water ports 180 may be provided at both ends of the cooling water jacket 182 so that cooling water may be circulated through the cooling water ports 180.

Meanwhile, the rotating shaft sealing device 100 according to an embodiment of the disclosure may further include a purge gas inflow port 170 provided in the inner housing 130 to prevent foreign substances from the chamber 20 of the semiconductor substrate processing apparatus 10 from flowing to the outside of the inner housing 130 of the rotating shaft sealing device 100. More specifically, a fine gap 172 is provided between the shaft 110 and the inner housing 130. The sealing portion 140 is provided on the opposite side of the flange portion 132 of the inner housing 130 connected to the chamber 20, thereby ultimately preventing foreign substances from the chamber 20 from being discharged to the outside the inner housing 130. To the contrary, the sealing portion 140 may prevent particles (foreign substances) generated from the bearing 150 disposed between the inner housing 130 and the outer housing 120 from flowing into the chamber 20 through the gap 172 between the shaft 110 and the inner housing 130. Meanwhile, the purge gas inflow port 170 is in fluid communication with the gap 172 between the shaft 110 and the inner housing 130, and thus, the purge gas supplied through the purge gas inflow port 170 may flow toward the sealing portion 140 and the chamber 20 through the gap 172, thereby preventing the process gas from the chamber 20 from flowing to the gap 172. In addition, negative pressure is formed in the purge gas inflow port 170 through an external pneumatic device, thereby sucking and removing foreign substances formed in the gap 172.

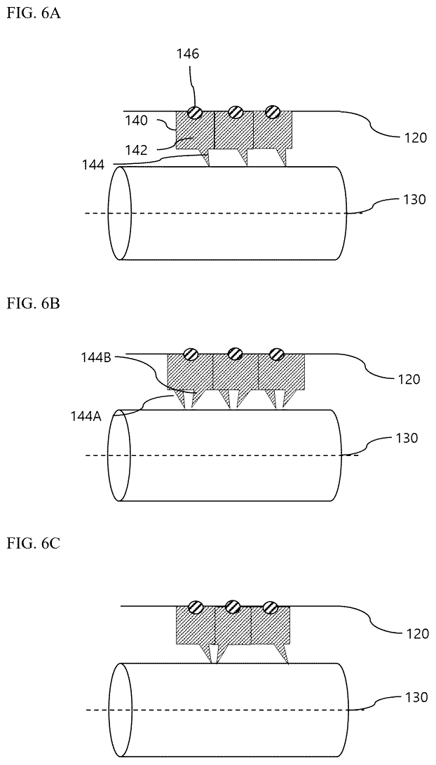

FIGS. 6A, 6B, and 6C illustrate various lip seals that may be used in the rotating shaft sealing device according to an embodiment of the disclosure.

Referring to FIGS. 6A, 6B, and 6C, each of the lip seals 140 used in the rotating shaft sealing device 100 according to an embodiment of the disclosure may have a shape in which a plurality of curved lip portions 144 are provided on one body portion 142.

As shown in FIG. 6A, when the three lip seals 140 are used, the lip portions 144 are curved in the same direction, as shown in FIG. 6B, lip portions 144A and 144B among the plurality of lip seals 140 may be curved in different directions, and as shown in FIG. 6C, each of the lip seals 140 includes the plurality of lip portions 144, and at least two of the plurality of curved lip portions 144 may be curved in different directions. In the case of FIG. 6A, when a vacuum is formed in the upper direction, all the lip portions 144 have shapes curved to the right to prevent foreign substances from the rotating shaft sealing device 100 of each of the lip seals 140 from flowing to the chamber 20, and in the case of FIG. 6B, even though a vacuum is formed in either the upper direction or the lower direction, the lip portion 144A or the lip portion 144B may respond or even though one lip portion 144A is consumed or damaged, the other lip portion 144B may respond.

In an embodiment, an annular anti-rotation member 146 may be provided on an outer circumferential surface of each of the lip seals 140 toward the outer housing 120 to prevent relative rotation of each of the lip seals 140 with the outer housing 120 within the outer housing 120. The anti-rotation member 146 serves to further pressurize the lip seal 140 toward the inner housing 130. In addition, the friction between the anti-rotation member 146 and the lip seal 140 is great compared to when there is no anti-rotation member 146, that is, when the lip seal 140 directly contacts an inner circumferential surface of the outer housing 120. Accordingly, the anti-rotation member 146 may suppress the lip seal 140 from rotating relative to the outer housing 120 within the outer housing 120.

In addition, when the rotating shaft sealing device 100 is disassembled and assembled for reasons such as damage and inspection, even though the surface roughness of the outer housing 120 is relatively rough, the anti-rotation member 146 rubs against the inner circumferential surface of the outer housing 120 during a disassembly and assembly process, and thus the sealing portion 140 may minimize damage caused by low surface roughness of the outer housing 120. In addition, even though the anti-rotation member 146 is damaged to some extent, there is an advantage that the anti-rotation member 146 is reusable, and thus the rotating shaft sealing device 100 may be more easily disassembled and assembled.

According to the rotating shaft sealing device and the semiconductor substrate processing apparatus using the same according to the above-described embodiments, the sealing portion makes line contact with a rotating object while replacing the magnetic fluid seal, which may minimize friction, and thus, a separate supply of lubricant is not required, thereby making the structure very compact and simple.

The rotating shaft sealing device and the semiconductor substrate processing apparatus using the same may prevent foreign substances such as particles from the semiconductor substrate processing apparatus from flowing into the rotating shaft sealing device, and the rotating shaft sealing device may include the cooling water jacket, which keeps the temperature of the sealing portion low, thereby extending the life of the sealing portion.

The rotating shaft sealing device may allow purge gas to flow to an upper part of the sealing portion and to be discharged to the semiconductor substrate processing apparatus, thereby preventing foreign substances generated in the semiconductor substrate processing apparatus from flowing into the sealing portion.

In the above, the disclosure has been described with specific details such as specific components, the limited embodiments and the drawings, but these are only provided to facilitate a more general understanding of the disclosure, the disclosure is not limited to the above embodiments, and those skilled in the art may achieve various modifications and changes based on the description.

Therefore, the spirit of the disclosure should not be limited to the above-described embodiments, and the claims described below as well as all modifications equally to or equivalent to the claims shall fall within the scope of the spirit of the disclosure.

What is claimed is:

1. A rotating shaft sealing device mounted on a semiconductor substrate processing apparatus processing a semiconductor substrate while rotating a semiconductor loading unit accommodating the semiconductor substrate, the rotating shaft sealing device comprising:
a shaft having one end connected to the semiconductor loading unit to transmit rotational force to the semiconductor loading unit;
an outer housing to which the other end of the shaft is fixedly coupled and accommodating the shaft therein;
an inner housing surrounding an outer circumferential surface of the shaft and installed on an inner surface of the outer housing, and having one end with a flange connected to a chamber of the semiconductor substrate processing apparatus;
one or more bearings provided between the outer housing and the inner housing to enable relative rotation between the outer housing and the inner housing; and
a sealing portion comprising a plurality of seals disposed in the inner housing and the outer housing to seal a gap between the inner housing and the outer housing.

2. The rotating shaft sealing device of claim 1, wherein the one or more bearings are disposed above the sealing portion so as to be closer to the flange of the inner housing coupled to the semiconductor substrate processing apparatus.

3. The rotating shaft sealing device of claim 1, wherein the plurality of seals are lip seals having curved lips formed on an inner circumferential surface of an annular sealing.

4. The rotating shaft sealing device of claim 3, wherein each of the lip seals has a plurality of curved lip portions provided on one body portion.

5. The rotating shaft sealing device of claim 4, wherein at least two of the plurality of curved lip portions are curved in different directions.

6. The rotating shaft sealing device of claim 1, wherein the inner housing includes a cooling water jacket provided in a part surrounding the shaft to cool between the shaft and the inner housing.

7. The rotating shaft sealing device of claim 1, wherein the inner housing includes a purge gas inflow port provided in the inner housing to prevent foreign substances from the semiconductor substrate processing apparatus from flowing to outside of the inner housing.

8. The rotating shaft sealing device of claim 7, wherein the gap between the shaft and the inner housing is in fluid communication with the purge gas inflow port, and purge gas supplied through the purge gas inflow port flows through the gap.

9. A semiconductor substrate processing apparatus processing a semiconductor substrate, the semiconductor substrate processing apparatus comprising:
a semiconductor loading unit rotatably disposed in a chamber; and
a rotating shaft sealing device performing a sealing function while rotating the semiconductor loading unit,
wherein the rotating shaft sealing device comprises:
a shaft having one end connected to the semiconductor loading unit to transmit rotational force to the semiconductor loading unit;
an outer housing to which the other end of the shaft is fixedly coupled and accommodating the shaft therein;
an inner housing surrounding an outer circumferential surface of the shaft and installed on an inner surface of the outer housing, and having one end with a flange connected to the chamber of the semiconductor substrate processing apparatus;
one or more bearings provided between the outer housing and the inner housing to enable relative rotation between the outer housing and the inner housing; and
a sealing portion comprising a plurality of seals disposed in the inner housing and the outer housing to seal a gap between the inner housing and the outer housing.
